(19) United States
(12) Patent Application Publication
(10) Pub. No.: US 2004/0226600 A1
(43) Pub. Date: Nov. 18, 2004

(54) Gas control assembly for controlling the supply of gas to unvented gas appliances

(76) Inventors: Edward Starer, Forest Hills, NY (US); George William Kraus II, North Olmsted, OH (US)

Correspondence Address: Edward Starer, 72-11 Austin Street, Forest Hills, NY, 11375, US

(21) Appl. No.: 10/805,968

(22) Filed: Mar. 22, 2004

Related U.S. Application Data
(63) Continuation-in-part of application No. 09/837,312, filed on Apr. 18, 2001, now Pat. No. 6,717,044.

(51) Int. Cl. H01L 35/02

(52) U.S. Cl. 136/224; 136/242

(57) ABSTRACT

An improved gas pilot control apparatus with an improved thermopile construction comprised of a consolidated thermocouple and thermopile capable of providing multiple EMF signals to operate a gas valve, transmitter/receiver and other components when positioned relative to a pilot flame. The improved thermopile requires a pilot flame of typically 500 BTU/hr to generate the EMF milli voltage required by modern gas valves to maintain reliable, rapid and safe operation of the appliance. The improved thermopile is electrically connected to an electromagnetic valve that controls the flow of gas from the source of supply to the pilot and main burner. The thermopiles are electrically connected to electromagnetic valves and to a transmitter/receiver that remotely control the flow of gas to the main burner.

### FIELD OF THE INVENTION

This invention relates to, but is not limited to, the control of combustible gases in vented and unvented gas appliances such as room heaters, gas fireplaces and log sets, patio heaters, and the heat provided from them.

### BACKGROUND OF THE INVENTION

Vented and unvented gas appliances such as room heaters and gas fired artificial logs are meeting the requirements of commercial and residential heating needs because of their use of energy efficient, clean-burning natural and liquid propane gas and the simplicity of installation. Safe operation of the unvented appliances is enabled through the use of an oxygen detection safety-pilot, or ODS.

A typical ODS system consists of an oxygen sensitive pilot burner and EMF generators in the form of a thermocouple and or a thermopile positioned in the pilot flame and a safety shutoff valve. When a vent-free gas appliance is operating in a room with a normal oxygen level of 20.9% the pilot flame of the ODS system is in contact with the ODS thermocouple and or thermopile that generates the necessary EMF needed to hold the normally closed electromagnetic valve in the open position. If the oxygen level in the room drops to about 19% the pilot flame begins to lift-off the ODS pilot burner. The thermocouple and or thermopile begin to cool to a point where there is an insufficient EMF generated to hold the electromagnetic gas valve open and the gas supply is shut off. U.S. Pat. No. 5,674,065 issued Oct. 7, 1997 to Grando, et al. for APPARATUS FOR CONTROLLING THE SUPPLY OF GAS TO AND HEAT FROM UNVENTED GAS HEATING APPLIANCES shows an electromagnetic valve connected to a gas supply line and an ODS pilot assembly comprised of an oxygen depletion sensor a thermocouple and a thermopile controlling the flow of gas to the pilot and a main gas burner. Grando et al. teaches that the omission of a thermocouple sacrifices the safety provided by the intentionally low voltage of the thermocouple. The thermocouple is instantly responsive to the ODS, whereas a period of time is required for the thermopile to sufficiently close the valve and interrupt the flow of gas.

U.S. Pat. No. 5,397,233 issued Mar. 14, 1995 to Eavenson, et al. for ASSEMBLY FOR CONTROLLING THE FLOW OF GAS FOR GAS FIRED ARTIFICIAL LOGS shows a main gas burner, a pilot including an oxygen detection sensor, and a fully automatic gas valve that controls the flow of gas to the pilot and main burner. Eavenson et al. teaches that the flow of gas to the gas fired fireplace logs can be safely and effectively controlled by a thermostat without using a thermocouple. Eavenson uses a thermopile having an output of at least 250 millivolts that is operatively connected to the gas valve and to the thermostat if the thermopile is spaced at least half an inch from the pilot and its oxygen detection sensor.

A typical ODS is a precisely designed, oxygen sensitive pilot. The pilot flame typically burns 450 BTU's of liquid propane gas per hour or 750 BTU's of natural gas per hour for optimum performance. The separate thermocouple and thermopile assemblies attached to the ODS pilot bracket and in contact with the pilot flame generate an EMF millivoltage within a narrow range and are incapable of generating an EMF sufficient to activate electromagnetic gas valves if the generators are improperly placed within a pilot flame or if the fixed heat generated by the pilot flame is insufficient to heat the thermocouple and thermopile. As the number of thermopiles needed to operate gas controls and remote controls increases, the pilot flame becomes less capable of heating the generators sufficiently to provide the necessary EMF to reliably activate an electromagnetic gas valve resulting in nuisance shutoffs and unreliable operation. In addition as the number of thermopiles required by modern gas valves to operate the gas valve, thermostats and transmitter/receivers increases, the ODS pilot assembly grows in size demanding a larger physical space in space efficient designed appliances.

### SUMMARY OF THE INVENTION

This invention allows for a reduction in the physical size of the ODS pilot apparatus through the use of a combined thermocouple and thermopile (s), maintains a smaller pilot flame which utilizes a reduced BTU/hour volume of liquid propane or natural gas while providing faster response to a lifting flame resulting from reduced oxygen levels, generates multiple EMF signals to operate the multiple functions of modern gas control valves and remote controlled devices utilized in unvented gas appliances such as room heaters, gas fireplace logs and gas fireplaces.

Specifically, the invention is comprised of an improved thermopile construction as presented in patent application Ser. No. 09/837,312 Thermopile Construction With Multiple EMF Outputs and patent application. Ser. No. 09/849,118 A Combined Thermocouple and Thermopile Capable of Generating Multiple EMF Signals. The invention is comprised of a consolidated thermocouple and thermopile (s) capable of providing multiple EMF signals that operate multiple functions of a gas control valve, thermostat and transmitter/receiver when positioned relative to a pilot flame generated by an ODS (oxygen detection sensor) or standard pilot commonly found in vented appliances. The reduced mass of the consolidated thermocouple and thermopile (s) when positioned relative to a pilot flame enable the ODS to use a pilot flame as low as 450 BTU/hr when using liquid propane gas and 750 BTU/hr when using natural gas to generate the EMF signals required by modern gas valves to maintain reliable, rapid response and safe operation of the appliance. The improved thermopile is electrically connected to an electromagnetic valve that controls the flow of gas from the source of supply to the pilot and main electromagnetic valves and to a thermostat and transmitter/receiver that control the flow of gas to the main burner. electromagnetic valves and to a thermostat and transmitter/receiver that control the flow of gas to the main burner.

### BRIEF DESCRIPTION OF THE DRAWING

The foregoing objects of the invention and novel features are depicted in the accompanying drawings in which:

FIG. 1 is a schematic view of a typical gas pilot assembly with separate thermopile and thermocouple.

FIG. 2 is a schematic view of a typical ODS gas pilot assembly with separate thermocouple and thermopile.

FIG. 3 is a schematic view of a gas and heat control assembly.

FIG. 4 is a schematic view of a typical pilot assembly with an improved thermopile, pilot and mounting bracket.

FIG. 5 is a schematic view of the novel ODS assembly with an improved thermopile, ODS pilot and mounting bracket.

### DETAILED DESCRIPTION OF THE INVENTION

FIG. 1 shows a typical exemplary pilot burner 23 held by bracket 22. Fittings for connecting the gas supply tube to the pilot burner 23 is designated at 28. Leads for connecting thermocouple 24 and thermopile 25 to safety gas valve and electronic circuitry controlling remote controlled thermostats and other devices are shown as 27 and 26.

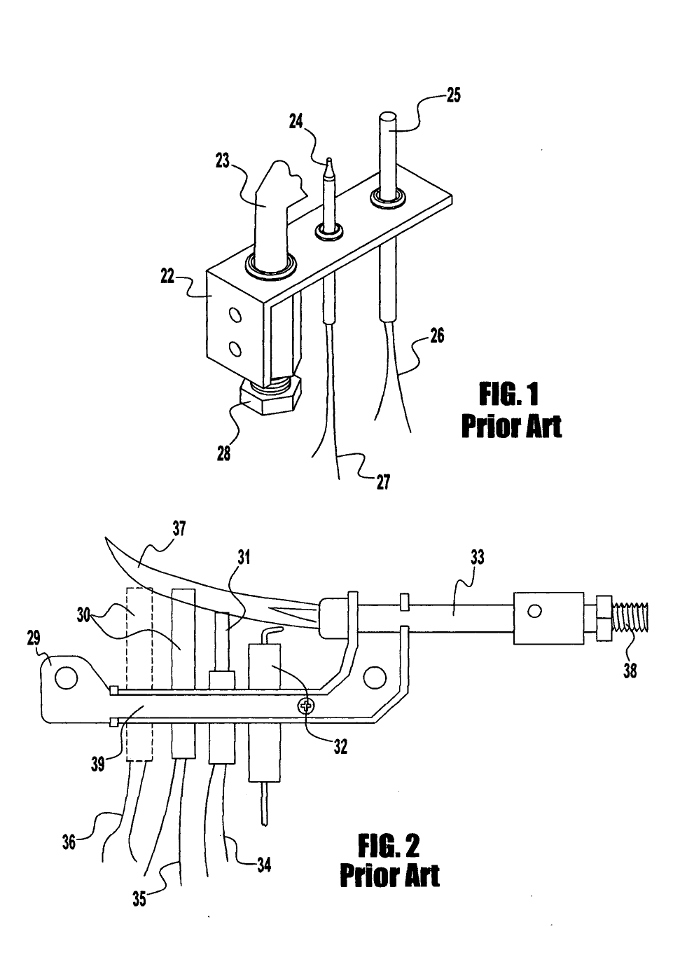

FIG. 2 shows a typical exemplary ODS pilot burner 33 held by bracket 29. Fittings for connecting the gas supply tube to the ODS pilot burner is designated at 38. A typical thermocouple 31 is fastened to bracket 29 by clamp 39. Thermopile (s) 30 are fastened to bracket 29 and positioned so as to be in intimate contact with flame 37. Igniter 32 is positioned near the pilot outlet to provide a spark sufficient to light the gas/air mixture issuing from the pilot when a gas valve is opened by manual or remote means. Flame 37 is also in intimate contact with one or more thermopiles 30.

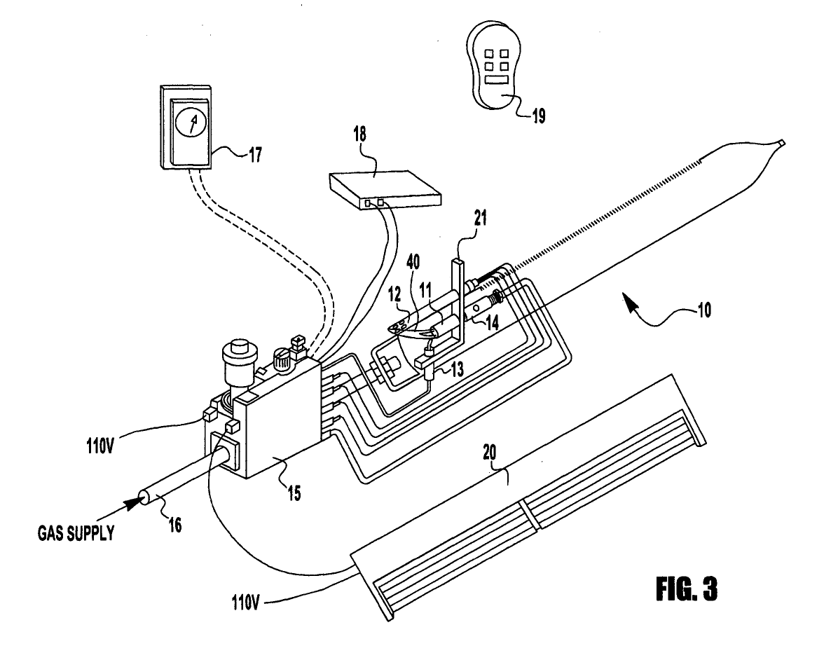

FIG. 3 illustrates a typical control assembly for gas fired appliances, generally indicated at 10. The control assembly comprises and ODS pilot 11, and improved thermopile 12, a spark igniter 13 and a mounting bracket21. The sensing portion of a conventional oxygen detection safety device (ODS) 14 is integrated with pilot 11. An improved thermopile 12 is installed as part of an ODS as the means of sensing heat from the pilot flame 40. When an unvented gas appliance equipped with an ODS device is operating in a room with a normal oxygen level of 20.9% the pilot flame of the ODS system is in contact with the improved thermopile 12 that generates the necessary EMF required to hold the normally closed electromagnetic gas valve 15 in the open position. If the oxygen level in the room drops to about 19% the pilot flame begins to lift-off the ODS tip and away from the improved thermopile. The improved thermopile 12 begins to cool to a point where there is an insufficient EMF to maintain the gas safety valve in the open position and the electromagnetic gas valve 15 closes the gas supply from the gas supply line 16.

A modern gas valve provides full burner flame modulation with temperature control and main burner shut-off. The flame and fan 20 is controlled by either a hand held remote 19 or a hardwired wall switch thermostat 17. Power for the remote control is supplied by a battery (not shown). Power for the gas valve safety circuit is supplied by an improved thermopile. Power for the transmitter/receiver 18 is supplied by the improved thermopile.

As more thermally responsive devices are added to the ODS pilot assembly, to generate the EMF required for the control of the gas valve and transmitter/receiver, the ODS pilot flame is less able to heat the generators sufficiently for the generators to produce the required EMF to reliably activate the gas valve and transmitter. It is for this reason that the present invention utilizes a consolidated thermocouple and thermopile (s) 12 (FIG. 3, 4) and 22 (FIG. 5). The thermocouple portion of the improved thermocouple and thermopile assembly provides a reduced thermoelectric output desired for the rapid shut-off of the gas supply to the gas valve. The thermopile portion of the assembly provides an EMF level suitable to activate thermostatic controls and receiver/transmitter for handheld remote controls.

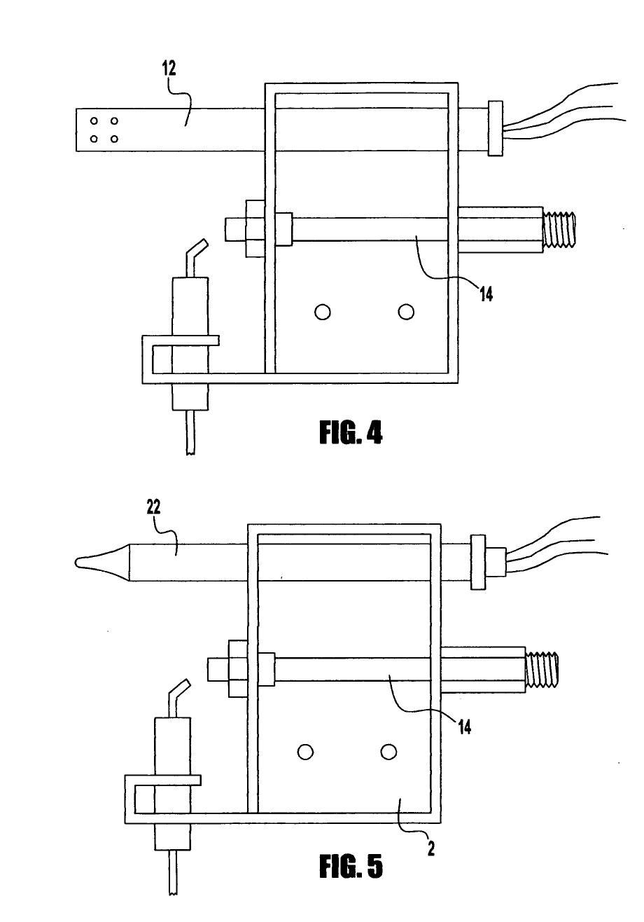

FIGS. 4 and 5 show two different configurations of an improved thermopile construction 12 and 22 and their positioning relative to the ODS pilot 14 and ODS pilot bracket 22. According to the present invention the improved thermopile is preferably mounted in close proximity to the pilot flame.

Those skilled in the art will understand the nature of the invention from the foregoing and the manner in which it achieves and realizes all of the objectives as set forth in the foregoing. As stated the combined thermocouple and thermopile device will react quickly to shut a gas supply off when the oxygen level in a room reaches about 19%. The combined thermocouple and thermopile assembly reduces the amount of energy required to maintain a suitable output in the range of 24-32 millivolts for the thermocouple and 250 or 750 millivolts or some combination of millivoltage suitable for the operation for the operation of gas valve and remote controlled devices.

The foregoing disclosure is representative of a preferred embodiment of the invention and is to be interpreted in an illustrative rather than a limiting sense, the invention to be accorded the full scope of the claims appended hereto.

What is claimed is:

1. An assembly for controlling the temperature of an area and the flow of gas in a vented or unvented gas appliance through an improved thermopile construction capable of producing multiple EMF outputs when positioned in close proximity to a pilot flame and generating an EMF signal for the control of the main gas flow through a gas control valve, a second EMF signal to control the modulation of gas to a main burner and a third EMF signal to control a receiver/transmitter for the remote control of other elements of the appliance.

2. The invention of claim 1 wherein the thermocouple portion of the improved thermopile construction generating an EMF in the range of 24-32 millivolts when heated by the pilot flame.

3. The invention of claim 1 wherein the first thermopile of the improved thermopile apparatus generates an EMF in the range of 250 millivolts.

4. The invention of claim 1 wherein the second thermopile of the improved thermopile apparatus generating a second EMF in the range of 750 millivolts required by a transmitter/receiver and third electromagnetic gas valve.

5. The invention of claim 1 wherein the improved thermopile apparatus is positioned in close proximity to a pilot flame.
